(19) United States
(12) Patent Application Publication
(10) Pub. No.: US 2026/0240022 A1
(43) Pub. Date: Aug. 13, 2026

(54) CIRCUIT BOARD AND SEMICONDUCTOR PACKAGE COMPRISING SAME

(71) Applicant: LG INNOTEK CO., LTD., Seoul (KR)

(72) Inventors: Sang Il KIM, Seoul (KR); Jae Man PARK, Seoul (KR); Dong Hwa LEE, Seoul (KR); Seon HEO, Seoul (KR)

(73) Assignee: LG INNOTEK CO., LTD., Seoul (KR)

(21) Appl. No.: 19/145,629

(22) PCT Filed: Jan. 5, 2024
(86) PCT No.: PCT/KR2024/000235

§ 371 Date: Jul. 3, 2025

(30) Foreign Application Priority Data
Jan. 5, 2023 (KR) 10-2023-0001906

(51) Int. Cl. H10W 70/685; H10W 70/695

(52) U.S. Cl. CPC H10W 70/686; H10W 70/695

(57) ABSTRACT

A circuit board according to an embodiment includes a first insulating layer; and a second insulating layer disposed on the first insulating layer, and wherein the first insulating layer has a first dielectric constant, the second insulating layer has a second dielectric constant smaller than the first dielectric constant, and the first dielectric constant of the first insulating layer satisfies a range of 9 to 15 (@10 GHz).

### TECHNICAL FIELD

An embodiment relates to a circuit board, and more particularly, to a circuit board capable of improving antenna performance and a semiconductor package comprising the same.

### BACKGROUND ART

Recently, in order to meet a demand for wireless data traffic, efforts have been made to develop an improved 5G (5th generation) communication system or a pre-5G communication system.

The 5G communication system uses ultra-high frequency (mm-Wave) bands (sub 6 GHZ, 28 GHZ, 38 GHZ, or higher frequencies) to achieve high data transfer rates. This high frequency band is called mmWave due to the length of the wavelength.

In order to reduce a path loss of radio waves and increase a transmission distance of radio waves in the ultra-high frequency band, in the 5G communication system, integration technologies such as beamforming, massive multi-input multi-output (massive MIMO), and array antennas have been developed.

Considering that it may be composed of hundreds of active antennas of wavelengths in the frequency bands, an antenna system becomes large relatively.

Meanwhile, circuit boards applied to such antenna systems are continuously required to improve the characteristics of miniaturization and thinning of a substrate structure.

In addition, the circuit board includes an insulating layer having a high dielectric constant to increase a number of antenna patches disposed on a substrate of limited size.

At this time, as the dielectric constant of the insulating layer increases, a size of the antenna patch can be reduced, and accordingly, the circuit board can be miniaturized.

However, the dielectric constant and dielectric loss of the insulating layer are in a trade-off relationship. That is, when the dielectric constant of the insulating layer is increased to reduce a size of the antenna patch, the dielectric loss (Df) of the insulating layer increases, which may cause a problem of deterioration of signal transmission characteristics of the circuit board.

### DISCLOSURE

### Technical Problem

An embodiment provides a circuit board having a novel structure and a semiconductor package including the same.

In addition, the embodiment provides a circuit board capable of reducing a size of an antenna pattern and a semiconductor package including the same.

In addition, the embodiment provides a circuit board capable of minimizing signal transmission loss and a semiconductor package including the same.

Preferably, the embodiment provides a circuit board having an insulating layer having a high dielectric constant and low dielectric loss and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; and a second insulating layer disposed on the first insulating layer, and wherein the first insulating layer has a first dielectric constant, wherein the second insulating layer has a second dielectric constant smaller than the first dielectric constant, and wherein the first dielectric constant of the first insulating layer satisfies a range of 9 to 15 (@10 GHZ).

In addition, the circuit board further comprises a first wiring layer disposed under the first insulating layer; and a second wiring layer disposed on the second insulating layer, and wherein the first wiring layer includes an antenna pattern radiating an antenna signal toward a lower side of the first insulating layer.

In addition, the first insulating layer has a dielectric loss in a range of 0.005 to 0.009.

In addition, the first insulating layer includes a first resin and a first filler disposed in the first resin, the second insulating layer includes a second resin and a second filler disposed in the second resin, and a property of at least one of the first resin and the first filler is different from a property of at least one of the second resin and the second filler.

In addition, a dielectric constant of the first resin of the first insulating layer is different from a dielectric constant of the second resin of the second insulating layer.

In addition, the dielectric constant of the first resin of the first insulating layer is greater than the dielectric constant of the second resin of the second insulating layer.

In addition, a dielectric loss of the first filler of the first insulating layer is different from a dielectric loss of the second filler of the second insulating layer.

In addition, the dielectric loss of the first filler of the first insulating layer is smaller than the dielectric loss of the second filler of the second insulating layer.

In addition, the circuit board further comprises a third insulating layer disposed between the first insulating layer and the second insulating layer, and wherein a dielectric constant of the third insulating layer is different from at least one of the dielectric constants of the first and second insulating layers.

In addition, the dielectric constant of the third insulating layer is same as the dielectric constant of any one of the first and second insulating layers.

In addition, the dielectric constant of the third insulating layer has a value between the dielectric constant of the first insulating layer and the dielectric constant of the second insulating layer.

Meanwhile, a semiconductor package according to an embodiment includes a first wiring layer; a first insulating layer disposed on the first wiring layer; a second insulating layer disposed on the first insulating layer; a second wiring layer disposed on the second insulating layer; a connection part disposed on the second wiring layer; and a semiconductor device disposed on the connection part, wherein the first insulating layer has a first dielectric constant, the second insulating layer has a second dielectric constant smaller than the first dielectric constant, and the first dielectric constant of the first insulating layer satisfies a range of 9 to 15 (@10 GHz).

In addition, the first wiring layer includes an antenna pattern, and the semiconductor device includes a driving device that provides a transmission signal to the antenna pattern and processes a reception signal received through the antenna pattern.

In addition, the first insulating layer and the first wiring layer are antenna array layers that transmit a transmission signal to an outside or receive a reception signal from the outside, and the second insulating layer and the second wiring layer are driving layers that transmit the transmission signal to the antenna array layer or receive the reception signal from the antenna array layer and provide the reception signal to the semiconductor device.

### Advantageous Effects

The circuit board of the embodiment includes a first insulating layer and a second insulating layer disposed on the first insulating layer. The first insulating layer is a layer on which a first wiring layer corresponding to an antenna pattern is disposed, and the second insulating layer is a layer on which a second wiring layer corresponding to a driving pattern driving the antenna pattern is disposed. Accordingly, properties of the first insulating layer may be different from properties of the second insulating layer. Specifically, a dielectric constant of the first insulating layer may be greater than a dielectric constant of the second insulating layer. For example, the dielectric constant of the first insulating layer may satisfy a range of 9 to 15 (@10 GHz).

Therefore, the embodiment allows the dielectric constant of the first insulating layer on which the first wiring layer corresponding to the antenna pattern is disposed to have a value of 9 or more, thereby reducing a size of the antenna pattern. Through this, the embodiment can drastically reduce a size of the circuit board and the semiconductor package including the same.

In addition, the embodiment allows the dielectric constant of the first insulating layer to have a value of 15 or less so that the first insulating layer has a rigidity of a certain level or more and a dielectric loss of a certain level or less. Through this, the embodiment can solve a problem of the circuit board being greatly bent in a specific direction by the first insulating layer. The embodiment can allow a semiconductor device mounted in a semiconductor package including the same to operate stably. Through this, the embodiment can improve operating characteristics of an electronic product and/or a server to which the semiconductor package is applied, and further enhance the operating reliability.

Furthermore, properties of the second resin of the second insulating layer may be different from properties of the first resin of the first insulating layer. Preferably, the dielectric constant of the second resin of the second insulating layer may be smaller than the dielectric constant of the first resin of the first insulating layer. In addition, the properties of the second filler of the second insulating layer may be different from the properties of the first filler of the first insulating layer. Preferably, the dielectric loss of the second filler of the second insulating layer may be greater than the dielectric loss of the first filler of the first insulating layer. This may be by controlling the properties of the first filler of the first insulating layer so that the first insulating layer having a dielectric constant higher than a certain level has a dielectric loss lower than a certain level.

Therefore, the embodiment can allow the first insulating layer and the second insulating layer to have different properties according to a function of a wiring layer respectively disposed on the first insulating layer and the second insulating layer, thereby improving the electrical characteristics of the circuit board and improving the antenna characteristics of the antenna pattern provided on the circuit board. Furthermore, the embodiment can reduce the size of the antenna pattern provided on the circuit board, thereby miniaturizing the circuit board. Furthermore, the embodiment can improve the physical and/or electrical reliability of the circuit board, and can enable a semiconductor device mounted on a semiconductor package including the same to operate stably. Through this, the embodiment can improve the operating characteristics of an electronic product and/or a server to which the semiconductor package is applied, and further improve the operating reliability.

### DESCRIPTION OF DRAWINGS

FIG. 1 is a cross-sectional view showing a circuit board according to an embodiment.

FIG. 2 is a drawing for explaining properties of the first insulating layer of FIG. 1.

FIG. 3 is a plan view for explaining a size of an antenna pattern of a comparative example.

FIG. 4 is a plan view for explaining a size of an antenna pattern of an embodiment.

FIG. 5 is a drawing showing a semiconductor package including the circuit board of FIG. 1.

### BEST MODE

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, embodiments of the present invention will be described in detail with reference to the attached drawings.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package. Broadly, The semiconductor package may include various components or chips. The components or chips may include memory chips such as volatile memory (e.g., DRAM), non-volatile memory (e.g., ROM), flash memory, application processor chips such as a central processor (e.g., CPU), a graphics processor (e.g., GPU), a digital signal processor, an encryption processor, a microprocessor, a microcontroller, and logic chips such as an analog-to-digital converter and an ASIC (application-specific IC).

The device or chip may include an active device and/or a passive device.

The active device refers to a device that actively utilizes a nonlinear portion of signal characteristics. In addition, the passive device refers to a device that does not utilize a nonlinear signal characteristic even though both linear and nonlinear signal characteristics exist. For example, the active device may include a transistor, an IC semiconductor device, and the passive device may include a capacitor, a resistor, an inductor, and the like. The passive device may increase a signal processing speed of the semiconductor chip, which is the active device, or perform a filtering function. In addition, the chip may be a wireless communication chip that can be used for Wi-Fi or 5G communication.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In this case, the electronic device may be a smart phone, a personal digital assistant, a digital video camera, a digital still camera, a network system, a computer, a monitor, a tablet, a laptop, a netbook, a television, a video game, a smart watch, an automotive, or the like. However, the embodiment is not limited thereto, and may be any other electronic device that processes data in addition to these.

### —Circuit Board—

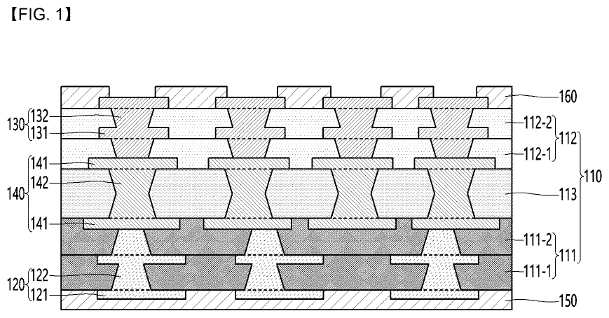

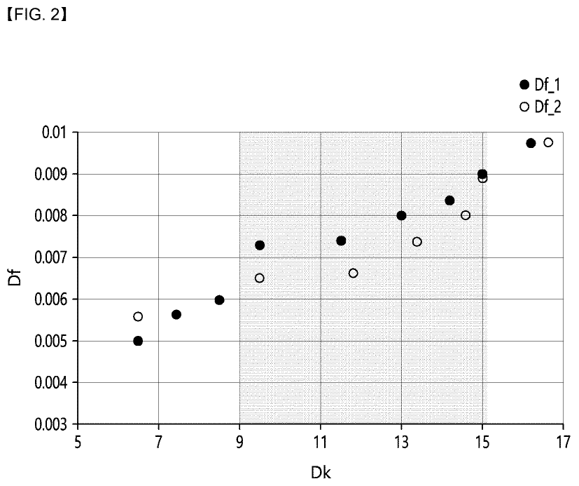

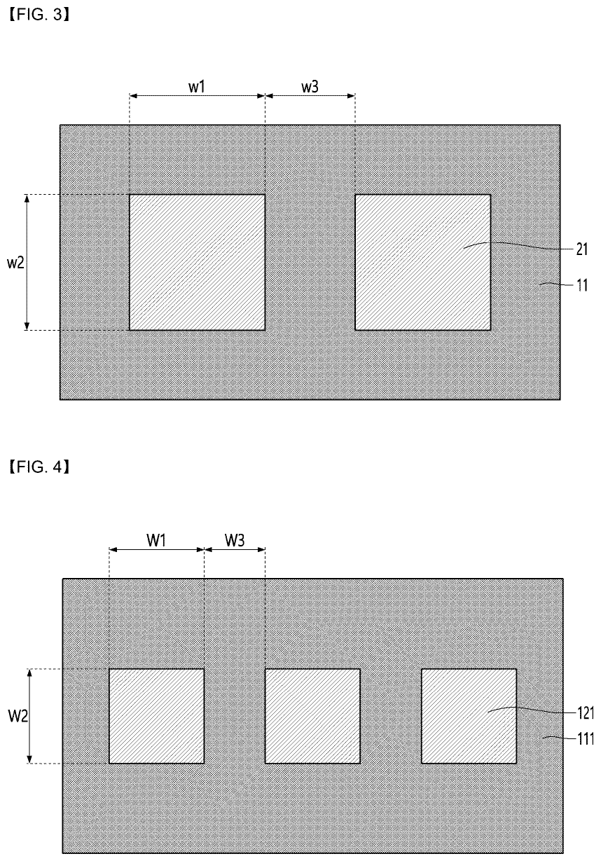

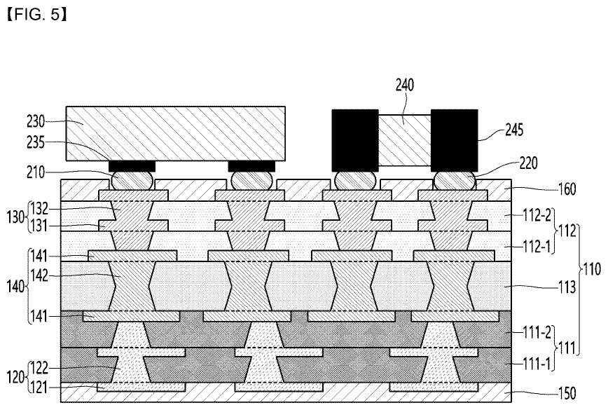

FIG. 1 is a cross-sectional view showing a circuit board according to an embodiment, FIG. 2 is a drawing for explaining the properties of the first insulating layer of FIG. 1, FIG. 3 is a plan view for explaining the size of the antenna pattern of a comparative example, and FIG. 4 is a plan view for explaining the size of the antenna pattern of an embodiment. The circuit board of FIG. 1 may be an antenna board including an antenna pattern.

Referring to FIG. 1, the circuit board 100 enables at least one semiconductor device to be mounted. In addition, the circuit board 100 of the embodiment enables it to be attached to a main board of an electronic device. The main board may mean a motherboard of the electronic device.

In addition, the semiconductor device mounted on the circuit board 100 may be one, or alternatively, may be two or more.

The circuit board 100 includes an insulating layer 110.

The insulating layer 110 has a multiple layer structure.

For example, the insulating layer 110 may include a plurality of layers having different properties. The properties include a dielectric constant and dielectric loss of each insulating layer. In addition, the properties may further include at least one of coefficient of thermal expansion (CTE), glass transition temperature, modulus, and shrinkage of each insulating layer.

That is, each layer of the insulating layer 110 may have different required characteristics and may have different properties corresponding to each required characteristic. Therefore, each layer of the insulating layer 110 may include different insulating materials.

For example, the insulating layer 110 may include a first insulating layer 111 and a second insulating layer 112 disposed on the first insulating layer 110.

At this time, the circuit board 100 of the embodiment may be a core board. For example, the insulating layer 110 may include a third insulating layer 113 disposed between the first insulating layer 111 and the second insulating layer 112. The third insulating layer 113 may be a core layer.

Therefore, the circuit board 100 of the embodiment may have a structure in which the first insulating layer 111 and the second insulating layer 112 are laminated in a thickness direction on both sides of the third insulating layer 113.

Hereinafter, the circuit board 100 of the embodiment is described as a core board, and accordingly, the second insulating layer 112 is a core layer. However, the embodiment is not limited thereto. For example, the circuit board 100 of the embodiment may be a coreless board that does not include a core layer.

The third insulating layer 113 may be a core layer, the first insulating layer 111 may be a lower insulating layer disposed under the third insulating layer 113, and the second insulating layer 112 may be an upper insulating layer disposed on the third insulating layer 113.

Each of the first insulating layer 111 and the second insulating layer 112 may have a different thickness from the third insulating layer 113. For example, the first insulating layer 111 and the second insulating layer 112 may have a smaller thickness than the third insulating layer 113.

The third insulating layer 113 may include a prepreg. For example, the third insulating layer 113 may increase a physical strength of the circuit board to improve warpage characteristics of the circuit board. The third insulating layer 113 may have a structure in which a fiber layer in a form of a fabric sheet, such as a glass fabric woven with glass yarn, is impregnated with an epoxy resin or the like. However, the third insulating layer 113 of the embodiment may include a fiber layer in a form of a fabric sheet woven with carbon fiber yarn.

Specifically, the third insulating layer 113 may include a resin and reinforcing fibers disposed in the resin. The resin may be an epoxy resin, but is not limited thereto. The resin is not particularly limited to an epoxy resin, and for example, it may include one or more epoxy groups in a molecule, or alternatively, the resin may include two or more epoxy groups, or alternatively, the resin may include four or more epoxy groups. In addition, the resin constituting the insulating layer 110 may include a naphthalene group, and for example, the resin may be an aromatic amine type, but is not limited thereto. For example, the resin may include bisphenol A type epoxy resin, bisphenol F type epoxy resin, bisphenol S type epoxy resin, phenol novolac type epoxy resin, alkylphenol novolac type epoxy resin, biphenyl type epoxy resin, aralkyl type epoxy resin, dicyclopentadiene type epoxy resin, naphthalene type epoxy resin, naphthol type epoxy resin, epoxy resin of a condensation product of phenols and aromatic aldehydes having a phenolic hydroxyl group, biphenyl aralkyl type epoxy resin, fluorene type epoxy resin, xanthene type epoxy resin, triglycidyl isocyanurate, rubber modified epoxy resin, and phosphorous epoxy resin, and may include naphthalene type epoxy resin, bisphenol A type epoxy resin, phenol novolac epoxy resin, cresol novolac epoxy resin, rubber modified epoxy resin, and phosphorous epoxy resin. In addition, the reinforcing fibers may be glass fibers, carbon fibers, aramid fibers (e.g., organic materials of the aramid series), nylon, inorganic materials of the silica series, or inorganic materials of the titania series. The reinforcing fibers may be disposed in a form of intersecting each other in a plane direction within the resin.

Meanwhile, the glass fibers, carbon fibers, aramid fibers (e.g., organic materials of the aramid series), nylon, inorganic materials of the silica series, or inorganic materials of the titania series may be used.

A thickness of the third insulating layer 113 may be 1.5 times or more, 2 times or more, 3 times or more, or 5 times or more a thickness of each of the first insulating layer 111 and the second insulating layer 112.

For example, the thickness of the third insulating layer 113 may satisfy a range of 100 μm to 600 μm. For example, the thickness of the third insulating layer 113 can satisfy a range of 120 μm to 550 μm. For example, the thickness of the third insulating layer 113 can satisfy a range of 150 μm to 500 μm.

If the thickness of the third insulating layer 113 is less than 100 μm, warpage characteristics of the circuit board may deteriorate. Furthermore, as the performance of semiconductor packages progresses, a number of insulating layers of the circuit board is also increasing. For example, the number of insulating layers of the circuit board may be 10 or more, 12 or more, 16 or more, or 20 or more. In addition, as the number of insulating layers of the circuit board increases, warpage of the circuit board should be minimized. In addition, if the thickness of the third insulating layer 113 is less than 100 μm, it is difficult to prevent the circuit board from bending, and thus a quality of the circuit board may deteriorate. For example, if the circuit board is bent, it may be difficult to form a through electrode included in the circuit board at an accurate position. In addition, if the circuit board is bent, problems such as a position of a semiconductor device being misaligned in a process of mounting the semiconductor device on the circuit board may occur. In addition, if the position of the semiconductor device is misaligned, the antenna characteristics implemented by the circuit board may deteriorate.

Meanwhile, if the thickness of the third insulating layer 113 exceeds 600 μm, an overall thickness of the circuit board increases, and thus an overall thickness of the semiconductor package may increase. That is, if the thickness of the third insulating layer 113 exceeds 600 μm, it may be difficult to slim down the circuit board and the semiconductor package.

The first insulating layer 111 and the second insulating layer 112 may have a thickness smaller than that of the third insulating layer 113.

For example, each of the first insulating layer 111 and the third insulating layer 113 may have a thickness in a range of 30 μm to 120 μm. Preferably, each of the first insulating layer 111 and the second insulating layer 112 may have a thickness in a range of 35 μm to 115 μm. More preferably, each of the first insulating layer 111 and the second insulating layer 112 may have a thickness of 40 μm to 110 μm.

If the thickness of the first insulating layer 111 or the second insulating layer 112 is less than 30 μm, the circuit pattern layer included in the circuit board 100 may not be stably protected. In addition, if the thickness of the first insulating layer 111 or the second insulating layer 112 exceeds 120 μm, the thickness of the circuit board 100 may increase, thereby increasing the thickness of the semiconductor package. In addition, if the thickness of the first insulating layer 111 or the second insulating layer 112 exceeds 120 μm, a thickness of the circuit pattern layer and a thickness of the through electrode may increase correspondingly. In addition, if the thickness of the circuit pattern layer and the thickness of the through electrode increase, it may be difficult to implement miniaturization, so that the circuit integration may decrease, and a signal transmission distance may increase, so that the signal transmission loss may increase. In addition, if the thickness of the first insulating layer 111 or the second insulating layer 112 exceeds 120 μm, the first insulating layer 111 or the second insulating layer 112 of the circuit board may not satisfy the required properties. The required properties may include the dielectric constant and dielectric loss required in the first insulating layer 111 or the second insulating layer 112. Furthermore, the required properties may further include at least one of a coefficient of thermal expansion and a glass transition temperature required in the first insulating layer 111 or the second insulating layer 112.

The first insulating layer 111 and the second insulating layer 112 may have different thicknesses.

For example, the first insulating layer 111 may have a thickness greater than that of the second insulating layer 112. For example, the thickness of the first insulating layer 111 may satisfy a range of 105% to 150% of a thickness of the second insulating layer 112. For example, a thickness of the first insulating layer 111 may satisfy a range of 106% to 140% of a thickness of the second insulating layer 112. For example, the thickness of the first insulating layer 111 may satisfy a range of 108% to 135% of the thickness of the second insulating layer 112.

Preferably, the first insulating layer 111 and the second insulating layer 112 may have different properties. For example, the dielectric constant of the first insulating layer 111 may be different from the dielectric constant of the second insulating layer 112. For example, the dielectric loss of the first insulating layer 111 may be different from the dielectric loss of the second insulating layer 112. Furthermore, at least one of the coefficient of thermal expansion and the glass transition temperature of the first insulating layer 111 may be different from at least one of the coefficient of thermal expansion and the glass transition temperature of the second insulating layer 112.

To this end, the first insulating layer 111 may include a first insulating material, and the second insulating layer 112 may include a second insulating material that is different from the first insulating material.

Preferably, the first insulating layer 111 may include a first resin, a first reinforcing fiber, and a first filler.

In addition, the second insulating layer 112 may include a second resin, a second reinforcing fiber, and a second filler.

At this time, a content of the first resin, a content of the first reinforcing fiber, and a content of the first filler of the first insulating layer 111 may be different from at least one of a content of the second resin, a content of the second reinforcing fiber, and a content of the second filler of the second insulating layer 112.

In addition, the properties of the first resin, the properties of the first reinforcing fiber, and the properties of the first filler of the first insulating layer 111 may be different from at least one of the properties of the second resin, the properties of the second reinforcing fiber, and the properties of the second filler of the second insulating layer 112.

Preferably, the properties of the first resin of the first insulating layer 111 may be different from the properties of the second resin of the second insulating layer 112. In addition, the properties of the first filler of the first insulating layer 111 may be different from the properties of the second filler of the second insulating layer 112.

Specifically, the dielectric constant of the first insulating layer 111 of the embodiment may be different from the dielectric constant of the second insulating layer 112. Preferably, the dielectric constant of the first insulating layer 111 may be greater than the dielectric constant of the second insulating layer 112.

In addition, the embodiment allows at least one of the properties of the first resin, the first reinforcing fiber, and the first filler of the first insulating layer 111 to be different from the properties of at least one of the second resin, the second reinforcing fiber, and the second filler of the second insulating layer 112, thereby making the dielectric constant of the first insulating layer 111 greater than the dielectric constant of the second insulating layer 112.

For example, the dielectric constant of the first insulating layer 111 may satisfy a range of 9 to 15 (@10 GHz). For example, the dielectric constant of the first insulating layer 111 may satisfy a range of 9.2 to 14.7 (@10 GHz). For example, the dielectric constant of the first insulating layer 111 may satisfy a range of 9.5 to 14.5 (@10 GHZ).

If the dielectric constant of the first insulating layer 111 is less than 9 (@10 GHz), a size of the antenna pattern provided in the circuit board may increase. In addition, if the size of the antenna pattern increases, the number of antenna patterns disposed in a limited space may decrease. In addition, if the size of the antenna pattern increases, the number of layers or plane area of the circuit board may increase in order to arrange the required number of antenna patterns.

For example, the size of the antenna pattern may be determined by a following Equation 1.

$$Antenna pattern size = \frac{- 1}{4 Dk} {( \frac{c}{f} )}^{2} \qquad [ Equation 1 ]$$

In Equation 1, Dk is a dielectric constant, f is a frequency, and c represents a speed of light.

Referring to Equation 1, a size of the antenna pattern is inversely proportional to the dielectric constant of the first insulating layer 111, and accordingly, as the dielectric constant of the first insulating layer 111 increases, the size of the antenna pattern may decrease, and as the dielectric constant of the first insulating layer 111 decreases, the size of the antenna pattern may increase.

Therefore, the embodiment allows the dielectric constant of the first insulating layer 111 on which a circuit pattern layer corresponding to the antenna pattern is disposed to have a value of 9 or more, thereby reducing the size of the antenna pattern.

Meanwhile, if the dielectric constant of the first insulating layer 111 exceeds 15, the rigidity of the first insulating layer 111 may decrease. For example, if the dielectric constant of the first insulating layer 111 exceeds 15, the degree of increase in the coefficient of thermal expansion of the first insulating layer 111 may be severe, and accordingly, a problem of the circuit board being greatly bent in a specific direction may occur.

Specifically, the coefficient of thermal expansion and modulus of the first insulating layer 111 according to the dielectric constant of the first insulating layer 111 are as shown in the following Table 1.

TABLE 1

| dielectric | coefficient of thermal | |
|---|---|---|
| constant(Dk) | expansion (ppm/° C.) | Modulus (GPa) |
| 8 | 11 | 25 |
| 11 | 17 | 20 |
| 15 | 19 | 18 |
| 17 | 30 | 12 |

Referring to Table 1, if the dielectric constant of the first insulating layer 111 exceeds 15, it can be seen that the corresponding coefficient of thermal expansion rapidly increases to a value of 30 ppm/° C. or more. In addition, if the dielectric constant of the first insulating layer 111 exceeds 15, it can be seen that the modulus of the first insulating layer 111 rapidly decreases to a value of 12 GPa or less. Therefore, the embodiment satisfies the dielectric constant of the first insulating layer 111 in a range of 9 to 15, thereby allowing the dielectric constant of the first insulating layer 111 to have a target range while maintaining the coefficient of thermal expansion and modulus of the first insulating layer 111 at a target level.

In addition, if the dielectric constant of the first insulating layer 111 exceeds 15, the dielectric loss (Df) of the first insulating layer 111, which increases in response to the increase in the dielectric constant, may fall outside the target range. Accordingly, the electrical characteristics of the circuit board may be deteriorated, and thus the antenna characteristics of the circuit board may be deteriorated.

That is, the embodiment allows the first insulating layer 111 to satisfy the target range of dielectric constant while satisfying the target range of dielectric loss by changing the content and properties of the first resin, the first filler, and the first reinforcing fiber provided in the first insulating layer 111.

The dielectric constant and the dielectric loss are proportional. For example, when the dielectric constant increases, the dielectric loss may also increase, and when the dielectric constant decreases, the dielectric loss may also decrease.

Therefore, the embodiment allows the first insulating layer 111 to have the target range of dielectric constant while having the target range of dielectric loss by changing the content and type of material of the first resin, the first filler, and the first reinforcing fiber of the first insulating layer 111.

The dielectric loss (Df) of the first insulating layer 111 of the embodiment may satisfy a range of 0.005 to 0.009. For example, the dielectric loss (Df) of the first insulating layer 111 of the embodiment may satisfy a range of 0.005 to 0.0085. For example, the dielectric loss (Df) of the first insulating layer 111 of the embodiment may satisfy a range of 0.005 to 0.008.

If the dielectric loss (Df) of the first insulating layer 111 is less than 0.005, the first insulating layer 111 may not satisfy a dielectric constant of the target range, and accordingly, the size of the antenna pattern disposed on the first insulating layer 111 may increase. In addition, if the size of the antenna pattern increases, the number of layers of the first insulating layer 111 may increase or the plane area of the first insulating layer 111 may increase, thereby increasing the volume of the circuit board and the semiconductor package including the same.

If the dielectric loss (Df) of the first insulating layer 111 exceeds 0.009, the transmission loss of the signal transmitted through the antenna pattern may increase, and thus radiation characteristics of the antenna pattern may deteriorate.

Referring to FIG. 2, the dielectric constant (Dk) and dielectric loss (Df) of the first insulating layer 111 are as follows. Df_1 of FIG. 2 is a graph showing the dielectric constant and dielectric loss relationship of the first insulating layer of Example 1, and Df_2 is a graph showing the dielectric constant and dielectric loss relationship of the first insulating layer of Example 2.

Referring to FIG. 2, in Examples 1 and 2, when the dielectric constant (Dk) of the first insulating layer 111 has a range of 9 to 15, it was confirmed that the corresponding dielectric loss (Df) had a range of 0.005 to 0.009. In addition, referring to FIG. 2, when the dielectric constant (Dk) of the first insulating layer 111 exceeds 15, it was confirmed that the dielectric loss (Df) rapidly increases to 0.01. Therefore, the embodiment makes it possible to minimize the transmission loss of the antenna pattern disposed on the first insulating layer 111 by making the dielectric constant (Dk) of the first insulating layer 111 have a range of 9 to 15 and the dielectric loss (Df) have a range of 0.005 to 0.009, thereby improving the electrical characteristics while minimizing the transmission loss and thereby improving the antenna characteristics. Therefore, the embodiment can improve the electrical characteristics and antenna characteristics of the antenna pattern while minimizing the size of the antenna pattern.

Meanwhile, the first insulating layer 111 can have the dielectric constant and dielectric loss in the above range by changing the type and content of the material of the first resin, the first filler, and the first reinforcing fiber constituting the first insulating layer 111.

Preferably, the first insulating layer 111 of the embodiment uses the first resin so that the dielectric constant of the first insulating layer 111 has a range of 9 to 15. For example, the embodiment uses the type of the material of the first resin and the content of the first resin so that the first insulating layer 111 has the dielectric constant in the above range. Furthermore, the first insulating layer 111 of the embodiment uses the first filler so that the dielectric loss of the first insulating layer 111 has a range of 0.005 to 0.009. For example, the embodiment allows the first insulating layer 111 to have the dielectric loss within the above range by changing the content of the first filler and the type of the material of the first filler.

Therefore, the embodiment adjusts the dielectric constant of the first insulating layer 111 using the properties of the first resin, and adjusts the dielectric loss of the first insulating layer 111 using the properties of the first filler, thereby allowing the first insulating layer 111 to satisfy the dielectric constant and dielectric loss within the target range, respectively.

Meanwhile, the first insulating layer 111 may be provided with a plurality of layers. For example, the first insulating layer 111 may include a first-first layer 111-1 and a first-second layer 111-2 disposed on the first-first layer 111-1. In addition, each of the first-first layer 111-1 and the first-second layer 111-2 may have a dielectric constant in a range of 9 to 15 and a dielectric loss in a range of 0.005 to 0.009.

Meanwhile, the second insulating layer 112 may have properties different from those of the first insulating layer 111.

For example, the second insulating layer 112 may have a dielectric constant different from that of the first insulating layer 111. For example, the second insulating layer 112 may have a dielectric constant lower than that of the first insulating layer 111.

For example, the properties of the second resin of the second insulating layer 112 may be different from the properties of the first resin of the first insulating layer 111. Preferably, at least one of the content and the type of the material of the second resin of the second insulating layer 112 may be different from at least one of the content and the type of the material of the first resin of the first insulating layer 111. Preferably, the dielectric constant of the second resin of the second insulating layer 112 may be smaller than the dielectric constant of the first resin of the first insulating layer 111.

In addition, the properties of the second filler of the second insulating layer 112 may be different from the properties of the first filler of the first insulating layer 111. Preferably, at least one of the content and the type of the material of the second filler of the second insulating layer 112 may be different from at least one of the content and the type of the material of the first filler of the first insulating layer 111. Preferably, the dielectric loss of the second filler of the second insulating layer 112 may be greater than the dielectric loss of the first filler of the first insulating layer 111. This may be by adjusting the properties of the first filler of the first insulating layer 111 so that the first insulating layer 111 having a dielectric constant higher than a certain level has a dielectric loss lower than a certain level.

Accordingly, the embodiment can make the first insulating layer 111 and the second insulating layer 112 have different properties according to the function of the wiring layer respectively disposed on the first insulating layer 111 and the second insulating layer 112, thereby improving the electrical characteristics of the circuit board and improving the antenna characteristics of the antenna pattern provided on the circuit board. Furthermore, the embodiment can reduce the size of the antenna pattern provided on the circuit board, thereby miniaturizing the circuit board. Furthermore, the embodiment can improve the physical and/or electrical reliability of the circuit board, and can enable the semiconductor device mounted on the semiconductor package including the same to operate stably. Through this, the embodiment can improve the operating characteristics of the electronic product and/or server to which the semiconductor package is applied, and further improve the operating reliability.

Meanwhile, the second insulating layer 112 can be provided in multiple layers. For example, the second insulating layer 112 may include a second-first layer 112-1 disposed on the third insulating layer 113 and a second-second layer 112-2 disposed on the second-first layer 112-1. However, the embodiment is not limited thereto, and the number of layers of the second insulating layer 112 may further increase.

Meanwhile, the third insulating layer 113 of one embodiment may have the same properties as the properties of either the first insulating layer 111 or the second insulating layer 112. For example, the third insulating layer 113 may have the same properties as the properties of the first insulating layer 111. For example, the third insulating layer 113 may have the same properties as the properties of the second insulating layer 112. Through this, the embodiment can provide the third insulating layer 113 using either one of the first insulating layer 111 and the second insulating layer 112, thereby providing ease in selecting materials for multiple insulating layers of the circuit board.

In addition, the properties of the third insulating layer 113 of another embodiment can be different from the properties of each of the first insulating layer 111 and the second insulating layer 112. However, the dielectric constant of the third insulating layer 113 can have a value between the dielectric constant of the first insulating layer 111 and the dielectric constant of the second insulating layer 112. Through this, the embodiment can solve mechanical reliability and electrical reliability problems that occur due to the difference in dielectric constant between the first insulating layer 111 and the second insulating layer 112. For example, the embodiment can alleviate the dielectric constant difference between the first insulating layer 111 and the second insulating layer 112 by the third insulating layer 113, thereby improving the mechanical reliability and electrical reliability of the circuit board and the semiconductor package including the same

The circuit board 100 of the embodiment includes a wiring layer disposed on the insulating layer 110. The wiring layer may include a circuit pattern layer and a through electrode depending on a location and function.

For example, the circuit board 100 may include a first wiring layer 120 disposed on the first insulating layer 111. The first wiring layer 120 may include a first circuit pattern layer 121 disposed on a surface of the first insulating layer 111 and a first through electrode 122 penetrating the first insulating layer 111.

In addition, the circuit board 100 may include a second wiring layer 130 disposed on a second insulating layer 112. The second wiring layer 130 may include a second circuit pattern layer 131 disposed on a surface of the second insulating layer 112 and a second through electrode 132 penetrating the second insulating layer 112.

In addition, the circuit board 100 may include a third wiring layer 140 disposed on a third insulating layer 113. The third wiring layer 140 may include a third circuit pattern layer 141 disposed on a surface of the third insulating layer 113 and a third through electrode 142 penetrating the third insulating layer 113.

The first to third circuit pattern layers 121, 131, and 141 can be formed by additive process, subtractive process, MSAP (Modified Semi Additive Process), and SAP (Semi Additive Process), which are conventional manufacturing processes of printed circuit boards, and detailed descriptions are omitted here, and a detailed description thereof is omitted here.

The first to third circuit pattern layers 121, 131, and 141 can be formed by at least one metal material selected from gold (Au), silver (Ag), platinum (Pt), titanium (Ti), tin (Sn), copper (Cu), and zinc (Zn). In addition, the first to third circuit pattern layers 121, 131, and 141 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first to third circuit pattern layers 121, 131, and 141 may be formed of copper (Cu) which is relatively inexpensive.

Each of the first to third circuit pattern layers 121, 131, and 141 may have a thickness in a range of 5 μm to 30 μm. For example, each of the first to third circuit pattern layers 121, 131, and 141 may have a thickness in a range of 6 μm to 27 μm. Each of the first to third circuit pattern layers 121, 131, and 141 may have a thickness in a range of 7 μm to 23 μm. If the thickness of each of the first to third circuit pattern layers 121, 131, and 141 is less than 5 μm, resistance may increase. When the thickness of each of the first to third circuit pattern layers 121, 131, and 141 exceeds 30 μm, circuit miniaturization may be difficult, and thus circuit integration may decrease.

Meanwhile, the first circuit pattern layer 121 may be an antenna pattern that transmits a communication signal to an outside and receives a communication signal transmitted from the outside. At this time, the first circuit pattern layer 121 is disposed under the first insulating layer 111 having a dielectric constant in a range of 9 to 15. Accordingly, the embodiment can reduce a size of the antenna pattern of the first circuit pattern layer 121 compared to a comparative example. That is, as in Equation 1, the size of the antenna pattern can be determined by the dielectric constant of the first insulating layer 111.

That is, the dielectric constant of the insulating layer on which the antenna pattern of the comparative example is disposed had a range of 5 to 9. Therefore, referring to FIG. 3, the antenna pattern of the comparative example had a first width w1 in a first horizontal direction, a second width w2 in a second horizontal direction, and a first spacing w3 between the plurality of antenna patterns.

Meanwhile, referring to FIG. 4, the antenna pattern of the embodiment may have a third width W1 smaller than the first width w1 in the first horizontal direction, a fourth width W2 smaller than the second width w2 in the second horizontal direction, and a second spacing W3 smaller than the first spacing w3 between the plurality of antenna patterns.

Therefore, a first area occupied by an unit antenna pattern by the third width W1, the fourth width W2, and the second spacing W3 of the embodiment may be smaller than a second area occupied by an unit antenna pattern by the first width w1, the second width w2, and the first spacing w3 of the comparative example. For example, a reduction ratio of the first area with respect to the second area is as shown in Table 2 below.

TABLE 2

| Dk | 7 | 9 | 10 | 13 | 15 | 17 |
|---|---|---|---|---|---|---|
| Example 1 | 100% | 57% | 65% | 72% | 80% | 85% |
| Example 2 | 100% | 55% | 61% | 69% | 77.5% | 82% |

Referring to Table 2, the antenna pattern according to the embodiment is disposed on the first insulating layer 111 having a dielectric constant in a range of 9 to 15, and accordingly, the size of the antenna pattern can be reduced by at least 55% and at most 80% compared to the comparative example having a dielectric constant of less than 9. In addition, as the dielectric constant of the first insulating layer 111 increases, the size of the antenna pattern can be further reduced. However, if the dielectric constant of the first insulating layer 111 exceeds 15, the corresponding dielectric loss may not satisfy the target range, or the warpage characteristics of the circuit board may deteriorate.

Meanwhile, in FIG. 4, the antenna pattern is illustrated as having a square shape and being spaced apart in a length direction, but this is not limited thereto.

For example, the antenna pattern may have a circular shape.

For example, the antenna pattern may have a rhombus shape.

In addition, the antenna pattern may be disposed in a zigzag shape in the length direction.

The first to third through electrodes 122, 132, and 142 can penetrate each insulating layer. The first to third through electrodes 122, 132, and 142 can be disposed in a through hole penetrating each insulating layer. For example, the first to third through electrodes 122, 132, and 142 can be formed by filling the through hole with a conductive material.

The through hole can be formed by any one of a mechanical, laser, and chemical processing method. The through hole can be formed by a mechanical processing method such as milling, drilling, and routing. In addition, the through hole can use a UV or CO₂ laser method. In addition, the through hole can use a chemical processing method using a chemical including minosilane, ketones, etc.

When the through hole is formed, an inside of the through hole may be filled with any one metal material selected from copper (Cu), silver (Ag), tin (Sn), gold (Au), nickel (Ni), and palladium (Pd) to form the first to third through electrodes 122, 132, and 142. At this time, the filling of the conductive material may use any one of electroless plating, electrolytic plating, screen printing, sputtering, evaporation, inkjetting, and dispensing, or a combination thereof.

The circuit board 100 of the embodiment includes a protective layer.

Specifically, a first protective layer 150 may be disposed on a lower surface of the first insulating layer 111. The first protective layer 150 may be provided to cover the first circuit pattern layer 121. For example, the first circuit pattern layer 121 may be embedded in the first protective layer 150. However, the embodiment is not limited thereto, and at least a portion of the first circuit pattern layer 121 may not be covered by the first protective layer 150. For example, the first protective layer 150 may include at least one first opening that vertically overlaps the first circuit pattern layer 121.

Meanwhile, the circuit board may include a second protective layer 160 disposed on the upper surface of the second insulating layer 112. The second protective layer 160 may include at least one opening. Specifically, the second protective layer 160 may include at least one second opening that vertically overlaps the second circuit pattern layer 132.

The first protective layer 150 and the second protective layer 160 may include an insulating material. The first protective layer 150 and the second protective layer 160 may include various materials that can be applied and then cured by heating to protect surfaces of the insulating layer and the circuit pattern layer.

The first protective layer 150 and the second protective layer 160 may be solder resist layers containing organic polymer materials. For example, the first protective layer 150 and the second protective layer 160 may include an epoxy acrylate series resin. In detail, the first protective layer 150 and the second protective layer 160 may include a resin, a curing agent, a photoinitiator, a pigment, a solvent, a filler, an additive, an acrylic series monomer, and the like. However, the embodiment is not limited thereto, and the first protective layer 150 and the second protective layer 160 may be any one of a photo solder resist layer, a cover-lay, and a polymer material.

The thickness of the first protective layer 150 and the second protective layer 160 may be 1 μm to 20 μm. The thickness of the first protective layer 150 and the second protective layer 160 may be 1 μm to 15 μm. For example, the thickness of the first protective layer 150 and the second protective layer 160 may be 5 μm to 20 μm. When the thickness of the first protective layer 150 and the second protective layer 160 exceeds 20 μm, the overall thickness of the circuit board and the semiconductor package may increase. Meanwhile, although the circuit board is illustrated in the drawing as including the first protective layer 150 and the second protective layer 160, it is not limited thereto. For example, at least one of the first protective layer 150 and the second protective layer 160 may be omitted.

The circuit board of the embodiment includes a first insulating layer and a second insulating layer disposed on the first insulating layer. The first insulating layer is a layer on which a first wiring layer corresponding to an antenna pattern is disposed, and the second insulating layer is a layer on which a second wiring layer corresponding to a driving pattern driving the antenna pattern is disposed. Accordingly, properties of the first insulating layer may be different from properties of the second insulating layer. Specifically, a dielectric constant of the first insulating layer may be greater than a dielectric constant of the second insulating layer. For example, the dielectric constant of the first insulating layer may satisfy a range of 9 to 15 (@10 GHz).

Therefore, the embodiment allows the dielectric constant of the first insulating layer on which the first wiring layer corresponding to the antenna pattern is disposed to have a value of 9 or more, thereby reducing a size of the antenna pattern. Through this, the embodiment can drastically reduce a size of the circuit board and the semiconductor package including the same.

In addition, the embodiment allows the dielectric constant of the first insulating layer to have a value of 15 or less so that the first insulating layer has a rigidity of a certain level or more and a dielectric loss of a certain level or less. Through this, the embodiment can solve a problem of the circuit board being greatly bent in a specific direction by the first insulating layer. The embodiment can allow a semiconductor device mounted in a semiconductor package including the same to operate stably. Through this, the embodiment can improve operating characteristics of an electronic product and/or a server to which the semiconductor package is applied, and further enhance the operating reliability.

Furthermore, properties of the second resin of the second insulating layer may be different from properties of the first resin of the first insulating layer. Preferably, the dielectric constant of the second resin of the second insulating layer may be smaller than the dielectric constant of the first resin of the first insulating layer. In addition, the properties of the second filler of the second insulating layer may be different from the properties of the first filler of the first insulating layer. Preferably, the dielectric loss of the second filler of the second insulating layer may be greater than the dielectric loss of the first filler of the first insulating layer. This may be by controlling the properties of the first filler of the first insulating layer so that the first insulating layer having a dielectric constant higher than a certain level has a dielectric loss lower than a certain level.

Therefore, the embodiment can allow the first insulating layer and the second insulating layer to have different properties according to a function of a wiring layer respectively disposed on the first insulating layer and the second insulating layer, thereby improving the electrical characteristics of the circuit board and improving the antenna characteristics of the antenna pattern provided on the circuit board. Furthermore, the embodiment can reduce the size of the antenna pattern provided on the circuit board, thereby miniaturizing the circuit board. Furthermore, the embodiment can improve the physical and/or electrical reliability of the circuit board, and can enable a semiconductor device mounted on a semiconductor package including the same to operate stably. Through this, the embodiment can improve the operating characteristics of an electronic product and/or a server to which the semiconductor package is applied, and further improve the operating reliability.

FIG. 5 is a drawing showing a semiconductor package including the circuit board of FIG. 1.

Referring to FIG. 5, the semiconductor package may include at least one semiconductor device disposed on the circuit board.

For example, the semiconductor package may be an antenna package.

In this case, a lower layer (insulating layer and circuit pattern layer) located below the first insulating layer 111 in the circuit board of the semiconductor package may constitute an antenna array layer that radiates an antenna signal to the outside, and an upper layer located above the first insulating layer 111 may constitute a driving layer that provides the antenna signal to the antenna array layer or processes the antenna signal received from the antenna array layer.

In this case, the characteristics required for the antenna array layer and the driving layer may be different from each other. For example, the antenna array layer may use an insulating layer with a relatively high dielectric constant to enhance antenna characteristics. In addition, the antenna array layer may be provided with a circuit pattern layer with a relatively low wiring density to provide a more compact antenna device. For example, the driving layer may use an insulating layer with a relatively low dielectric constant to minimize signal transmission loss while enhancing signal processing characteristics. In addition, the driving layer may be provided with a circuit pattern layer having a relatively high wiring density.

Meanwhile, the semiconductor package may include a first connection part 210 and a second connection part 220. The first connection part 210 and the second connection part 220 may mean solder balls, but are not limited thereto.

A first semiconductor device 230 may be disposed on the first connection part 210. A terminal 235 of the first semiconductor device 230 may be electrically coupled to a circuit board through the first connection part 210.

A second semiconductor device 240 may be disposed on the second connection part 220. A terminal 245 of the second semiconductor device 240 may be electrically coupled to a circuit board through the second connection part 220.

In addition, the first semiconductor device 230 may be a driving device. For example, when the semiconductor package is an antenna package, the first semiconductor device 230 may be a driving device for driving the antenna package. The first semiconductor device 230 may provide a transmission signal to the antenna array layer so that an antenna signal may be transmitted to the outside. The first semiconductor device 230 may receive a reception signal from the antenna array layer, and may process and analyze a signal transmitted from the outside through the transmission signal.

In addition, the second semiconductor device 240 may be a device for supporting the operation of the first semiconductor device 230. For example, the second semiconductor device 240 may include a resistor, a capacitor, an inductor, and the like.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a first insulating layer; and
a second insulating layer disposed on the first insulating layer, and
wherein the first insulating layer has a first dielectric constant,
wherein the second insulating layer has a second dielectric constant smaller than the first dielectric constant, and
wherein the first dielectric constant of the first insulating layer satisfies a range of 9 to 15 (@10 GHz).

2. The circuit board of claim 1, further comprising:
a first wiring layer disposed under the first insulating layer; and
a second wiring layer disposed on the second insulating layer,
wherein the first wiring layer includes an antenna pattern radiating an antenna signal toward a lower side of the first insulating layer.

3. The circuit board of claim 1, wherein the first insulating layer has a dielectric loss in a range of 0.005 to 0.009.

4. The circuit board of claim 3, wherein the first insulating layer includes a first resin and a first filler disposed in the first resin,
wherein the second insulating layer includes a second resin and a second filler disposed in the second resin, and
wherein a property of at least one of the first resin and the first filler is different from a property of at least one of the second resin and the second filler.

5. The circuit board of claim 4, wherein a dielectric constant of the first resin of the first insulating layer is different from a dielectric constant of the second resin of the second insulating layer.

6. The circuit board of claim 4, wherein the dielectric constant of the first resin of the first insulating layer is greater than the dielectric constant of the second resin of the second insulating layer.

7. The circuit board of claim 4, wherein a dielectric loss of the first filler of the first insulating layer is different from a dielectric loss of the second filler of the second insulating layer.

8. The circuit board of claim 7, wherein the dielectric loss of the first filler of the first insulating layer is smaller than the dielectric loss of the second filler of the second insulating layer.

9. The circuit board of claim 4, further comprising:
a third insulating layer disposed between the first insulating layer and the second insulating layer, and
wherein a dielectric constant of the third insulating layer is different from at least one of the dielectric constants of the first and second insulating layers.

10. The circuit board of claim 8, wherein the dielectric constant of the third insulating layer is same as the dielectric constant of any one of the first and second insulating layers.

11. The circuit board of claim 9, wherein the dielectric constant of the third insulating layer has a value between the dielectric constant of the first insulating layer and the dielectric constant of the second insulating layer.

12. A semiconductor package comprising:
a first wiring layer;
a first insulating layer disposed on the first wiring layer;
a second insulating layer disposed on the first insulating layer;
a second wiring layer disposed on the second insulating layer;
a connection part disposed on the second wiring layer; and
a semiconductor device disposed on the connection part,
wherein the first insulating layer has a first dielectric constant,
wherein the second insulating layer has a second dielectric constant smaller than the first dielectric constant, and
wherein the first dielectric constant of the first insulating layer satisfies a range of 9 to 15 (@10 GHz).

13. The semiconductor package of claim 12, wherein the first wiring layer includes an antenna pattern, and
wherein the semiconductor device includes a driving device providing a transmission signal to the antenna pattern and processing a reception signal received through the antenna pattern.

14. The semiconductor package of claim 12, wherein the first insulating layer and the first wiring layer are antenna array layers transmitting a transmission signal to an outside or receiving a reception signal from the outside, and
wherein the second insulating layer and the second wiring layer are driving layers transmitting the transmission signal to the antenna array layer or receiving the reception signal from the antenna array layer and providing the reception signal to the semiconductor device.

15. The semiconductor package of claim 12, wherein the first insulating layer has a dielectric loss in a range of 0.005 to 0.009.

16. The semiconductor package of claim 15, wherein the first insulating layer includes a first resin and a first filler disposed in the first resin,
wherein the second insulating layer includes a second resin and a second filler disposed in the second resin, and
wherein at least one of the first resin and the first filler has a property different from that of at least one of the second resin and the second filler.

17. The semiconductor package of claim 16, wherein a dielectric constant of the first resin of the first insulating layer is different from a dielectric constant of the second resin of the second insulating layer, and
wherein a dielectric loss of the first filler of the first insulating layer is different from a dielectric loss of the second filler of the second insulating layer.

18. The semiconductor package of claim 17, wherein the dielectric constant of the first resin of the first insulating layer is greater than the dielectric constant of the second resin of the second insulating layer, and
wherein the dielectric loss of the first filler of the first insulating layer is smaller than the dielectric loss of the second filler of the second insulating layer.

19. The semiconductor package of claim 14, further comprising:
a third insulating layer disposed between the first insulating layer and the second insulating layer,
wherein a dielectric constant of the third insulating layer is different from at least one of the dielectric constants of the first and second insulating layers.

20. The semiconductor package of claim 18, wherein the dielectric constant of the third insulating layer has a value between the dielectric constant of the first insulating layer and the dielectric constant of the second insulating layer.
